(19) United States
(12) Patent Application Publication
(10) Pub. No.: US 2024/0290748 A1
(43) Pub. Date: Aug. 29, 2024

(54) MIXED ACTIVATING AND REDUCING AGENT FOR BONDING

(71) Applicant: Tokyo Electron Limited

(72) Inventors: Christopher NETZBAND, Albany, NY (US); Hirokazu AIZAWA, Albany, NY (US)

(73) Assignee: Tokyo Electron Limited, (US)

(21) Appl. No.: 18/586,259

(22) Filed: Feb. 23, 2024

Related U.S. Application Data
(60) Provisional application No. 63/447,693, filed on Feb. 23, 2023.

(51) Int. Cl. H01L 23/00; H05H 1/46

(52) U.S. Cl. CPC H01L 24/80; H05H 1/46; H01L 2224/80009; H01L 2224/80895; H01L 2224/80896; H05H 2245/40

(57) ABSTRACT

A method is provided for activating a first surface for bonding to a second surface. In some embodiments, the method includes exposing the first surface to a plasma that has a high electron density in a range between 1×10⁹ cm⁻³ and 1×10¹² cm⁻³ and a low electron temperature of less than 1 eV, and then bonding the first surface to the second surface. In some embodiments, the plasma is generated by a plasma generator using a slot-plane-antenna (SPA) technique. In some embodiments, the plasma also includes a reducing agent.

### CROSS-REFERENCE TO RELATED APPLICATION

This application claims priority to and the benefit of U.S. Provisional Application No. 63/447,693, filed Feb. 23, 2023, entitled “BONDING LAYER AND PROCESS,” which is incorporated herein by reference in its entirety for all purposes.

### FIELD OF THE DISCLOSURE

This disclosure generally relates to methods of manufacturing semiconductor devices, and more particularly relates to methods of bonding of multiple substrates.

### BACKGROUND

Wafer to wafer bonding, chip to chip bonding, and chip to wafer bonding (generally substrate to substrate bonding) are being implemented to continue Power-Performance-Area-Cost (PPAC) scaling for complex circuits such as are implemented in Systems on Chip (SOCs). Conventional bonding techniques, such as direct bonding and hybrid bonding, utilize high pressure and/or high temperature to achieve reliable oxide-to-oxide bonding adhesion between the substrates. Typically, conventional technologies or processes of bonding two substrates may have a high penetration depth into a bonding interface and may damage the materials at this interface through physical sputtering. For example, the materials at this interface may have their chemical states and compositions modified during this penetration. Improved lower temperature bonding technologies with excellent adhesion are thus desired.

### SUMMARY

According to one implementation, a method of bonding a first surface for bonding to a second surface may include exposing the first surface to a plasma having an electron density in a range between 1×10⁹ cm⁻³ and 1×10¹² cm⁻³, and including a reducing agent; and bonding the first surface to the second surface. In other embodiments, the electron density of the plasma is in a range between 1×10¹⁰ cm⁻³ and 1×10¹¹ cm⁻³.

The plasma may have an electron temperature of less than 1 eV. The electron temperature may be in a range between 0.2 eV and 0.8 eV. The electron temperature may be in a range between 0.3 eV and 0.7 eV. The method may include, before bonding the first surface to the second surface, exposing the second surface to the plasma. The method may include, after bonding the first surface to the second surface, annealing a bond interface between the first surface and the second surface.

According to another implementation, a method of activating a first surface for bonding to a second surface may include exposing the first surface to a plasma having an electron density in a range between 1×10⁹ cm⁻³ and 1×10¹² cm⁻³; and bonding the first surface to the second surface, and the plasma is generated by a plasma generator using a slot-plane-antenna (SPA) technique. In other embodiments, the electron density of the plasma is in a range between 1×10¹⁰ cm⁻³ and 1×10¹¹ cm⁻³.

The plasma may have an electron temperature of less than 1 eV. The electron temperature may be in a range between 0.2 eV and 0.8 eV. Before bonding the first surface to the second surface, the second surface may be also exposed to the plasma. After bonding the first surface to the second surface, a bond interface between the first surface and the second surface may be annealed.

According to yet another implementation, a method of activating a first surface for bonding to a second surface includes exposing the first surface to a plasma including a reducing agent; and bonding the first surface to the second surface. The plasma is generated by a plasma generator using a slot-plane-antenna (SPA) technique.

The reducing agent may be selected from a group consisting of H₂, H₂O, H₂O₂, CO, CO₂, NH₃, CH₄, SO₂, H₂S, and NO. The reducing agent may be selected from a group consisting of volatile organic compounds. One of the volatile organic compounds may be selected from a group consisting of C₂H₆, C₃H₈, C₄H₁₀, C₂H₄ and C₂H₂.

According to still yet another implementation, a chamber for activating a surface includes a first wafer carrier configured to hold a first wafer having a first surface facing up; a plasma generator configured to generate a plasma using a slot-plane-antenna (SPA) technique; a plasma inlet port connected to the plasma generator and configured to direct the plasma toward the first surface of the first wafer; and a reducing agent inlet port connected to a reducing agent supply to supply a reducing agent into the chamber. The plasma has an electron density in a range between 1×10⁹ cm⁻³ and 1×10¹² cm⁻³ and an electron temperature of less than 1 eV.

The plasma may have an electron temperature of less than 1 eV. The reducing agent may be selected from a group consisting of H₂, H₂O, H₂O₂, CO, CO₂, NH₃, CH₄, SO₂, H₂S, NO, and a volatile organic compound.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a bonding process according to conventional techniques.

FIGS. 2A-2D illustrate a process of using a particular plasma having a high density and a low ion energy during an activation of a bonding surface in accordance with some embodiments.

FIGS. 3A-3D illustrate a process of adding a reducing agent to a plasma gas during an activation of a bonding surface in accordance with some embodiments.

FIGS. 4A-4D illustrate a process of using a particular plasma having a high density and a low ion energy and adding a reducing agent to the particular plasma during an activation of a bonding surface in accordance with some embodiments.

FIG. 5 is a view illustrating a surface activation chamber in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used, or other changes may be made without departing from the spirit or scope of the present disclosure. The illustrative embodiments described in the detailed description are not meant to be limiting of the subject matter presented.

According to some embodiments, before bonding (e.g., fusion or hybrid bonding) a first bonding surface of a first wafer and a second bonding surface of a second wafer, at least the first bonding surface is activated by utilizing a plasma. The plasma may have a high electron density and low electron temperature. In some embodiments, a reducing agent is added to the plasma. After at least the first bonding surface is activated, the first and the second bonding surfaces can be brought together and bonded.

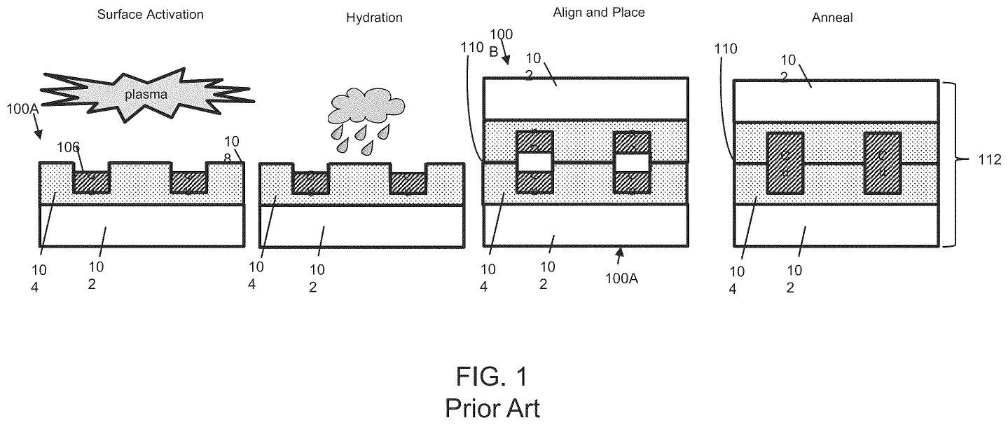

FIG. 1 illustrates a bonding process according to conventional techniques. Some operations of the process for bonding two substrates or wafers 100 (e.g., 100A and 100B) are illustrated. Some steps of the bonding process are illustrated in FIG. 1 merely for illustration purposes. The process as shown in FIG. 1 is abbreviated and simplified.

As shown in FIG. 1, a base substrate 102 of a wafer 100A is first provided. The base substrate 102 may include active devices, metallization, and other circuitry features. A dielectric layer 104 is then formed upon the base substrate 102 and has a bonding surface 108. After that, conductive contacts 106 of a conductive material (e.g., Copper (Cu)) are formed at or below the bonding surface 108 of the dielectric layer 104. The dielectric layer 104 may be an oxide, nitride, or carbide, as is well known and described elsewhere. The conductive contacts 106 can be recessed below (or lower than) the bonding surface 108 to ensure that, when two bonding surfaces (e.g., this bonding surface 108 and another bonding surface) are brought together, a strongly bonded dielectric-to-dielectric interface is formed prior to (without) the conductive contacts 106 protruding and contacting each other across the bonding interface 110.

As shown in FIG. 1, before the bonding, the bonding surface 108 is activated using a plasma (e.g., such as an N₂ or O₂ plasma) to prepare the surface 108 for bonding. Then, a hydration can be provided to further enhance the bonding capabilities of the bonding surface 108. Then, the bonding surface 108 of the wafer 100A and another bonding surface of another wafer 100B are aligned and brought into contact at a bonding interface 110. After that, an anneal step can be performed to improve the dielectric-to-dielectric bond and/or cause the conductive contacts to expand toward each other and create physical and electrical contacts as parts of a bonded structure 112.

However, the process as shown in FIG. 1 may cause a high penetration depth into the bonding interface 110 and may damage the materials at this bonding interface 110 through physical sputtering. Additionally, the materials at or adjacent to this bonding interface 110 may have their chemical states and compositions modified during this penetration. Improved bonding technologies are thus desired.

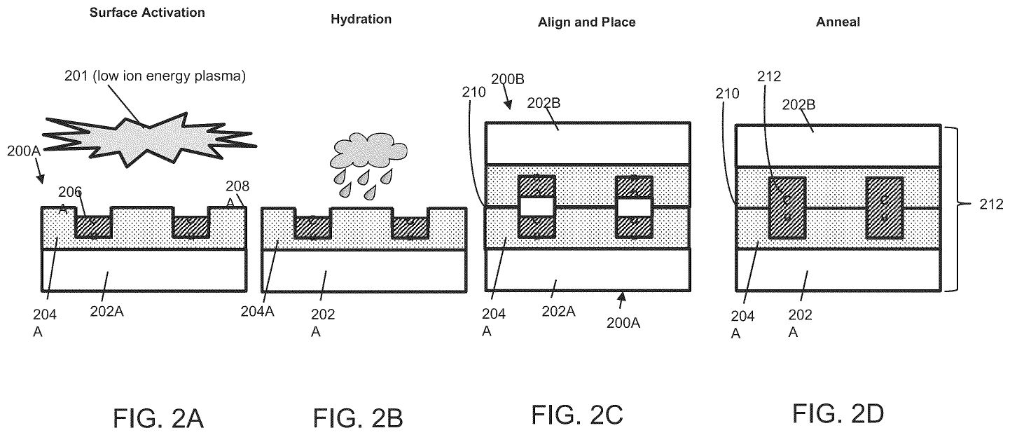

FIGS. 2A-2D illustrate a process of using a particular plasma having a high electron density and a low ion energy during an activation of a bonding surface (such as 208A in FIG. 2A) in accordance with some embodiments. An example bonding preparation technique for bonding two substrates or wafers 200 (such as 200A and 200B) is illustrated in accordance with some embodiments.

FIG. 2A illustrates a surface activation operation to at least one bonding surface (such as 200A) in accordance with some embodiments of the present disclosure. In some embodiments, a base substrate 202A of a wafer 200A is provided, and upon or within the base substrate 202A, circuitry and/or devices are formed (not shown). In some embodiments, a dielectric layer 204A is formed on or over the base substrate 202A. In some embodiments, conductive contacts 206A are formed on or in the dielectric layer 204A. In some embodiments, the conductive contacts 206A are made of a suitable conductive materials, such as copper, nickel, ruthenium, platinum, titanium, tungsten, and the like, or a combination thereof. In some embodiments, the conductive contacts 206A may be formed across or within one or more layers, such as back-end-of-line (BEOL) layers or front-end-of-line (FEOL) layers, of the wafer 200A. For the briefness and conciseness purposes, further detailed discussion on this process is omitted. For the illustration purpose, the conductive contacts 206 made of copper (Cu) will be used as an example. In some embodiments, after forming the conductive contacts 206A of Cu, the dielectric layer 204A is processed to activate the surface 208A thereof, and thus make it more susceptible to bonding at room temperature.

As shown in FIG. 2A, in some embodiments, the activation of the surface 208A is accomplished using a low ion energy plasma 201 to render the surface 208A hydrophilic and amenable to bonding without excessively damaging the conductive contacts 206A. In some embodiments, the low ion energy plasma 201 may have a high electron density and a low electron temperature (i.e., kinetic energy). In some embodiments, such a plasma is generated by a plasma generator (not shown) that uses a slot-plane-antenna (SPA) technique. A slot plane antenna (SPA), also known as a slot array antenna, is a specific type of slot antenna that includes multiple slots arranged in a regular pattern on a flat conducting surface, such as a metal plane. SPAs can be used in radar systems, wireless communication systems, and broadcasting applications due to their directional properties and high gain. SPAs can be designed to radiate or receive electromagnetic waves in specific directions, making them suitable for various applications requiring directional antenna patterns.

In some embodiments, the plasma 201 has a high electron density in a range between 1×10⁹ cm⁻³ and 1×10¹² cm⁻³, and in other embodiments, the plasma 201 has a high electron density in a range between 1×10¹⁰ cm⁻³ and 1×10¹¹ cm⁻³.

In an embodiment, the electron temperature of the plasma 201 is less than 1 eV. In another embodiment, the electron temperature of the plasma 201 is in a range between 0.2 eV and 0.8 eV. In yet another embodiment, the electron temperature of the plasma 201 is in a range between 0.3 eV and 0.7 eV. In still yet another embodiment, the electron temperature of the plasma 201 is in a range between 0.4 eV and 0.6 eV.

In some embodiments, the low ion energy plasma 201 can be e.g., an inductively coupled plasma (ICP), a capacitively coupled plasma (CCP), and a slotted plane antenna (SPA) plasma, and can be generated by using any plasma generating systems. As such, the surface 208A over the dielectric layer 204A is made ready for bonding.

By minimizing the ion energy of the plasma 201, ion bombardment and plasma penetration depth into a bonding interface 210 between the wafers 200A and 200B are minimized. By lowering the penetration depth into the bonding interface 210, the amount of conductive material that can be damaged or modified is limited or restricted to the top surface (e.g., 208A). While there may still be some resistive species present, the quantity will be much lower than that which would be present after a conventional plasma activation. Since bonding strength is primarily dependent on the surface quality, lowering the penetration depth will not lower the bond strength of the dielectric bond layer 204A at bond surface 208A.

As shown in FIG. 2B, the bond surface 208A is additionally processed by a hydration operation in accordance with some embodiments. As shown in FIG. 2C, the wafer 200A and another wafer 200B are brought together in accordance with some embodiments. In some embodiments, the surface of the other wafer 200B is similarly activated as the surface of the wafer 200A. As shown in FIG. 2D, thermal energy is applied to the wafers 200A and 200B to anneal the bond interface 210 formed between the wafers 200A and 200B, and to expand the conductive contacts (e.g., 206A) of the wafers 200A and 200B toward the bond interface 210 therebetween. As such, a resultant interconnect 212 between the wafers 200A and 200B has a reduced resistance and improved conductivity.

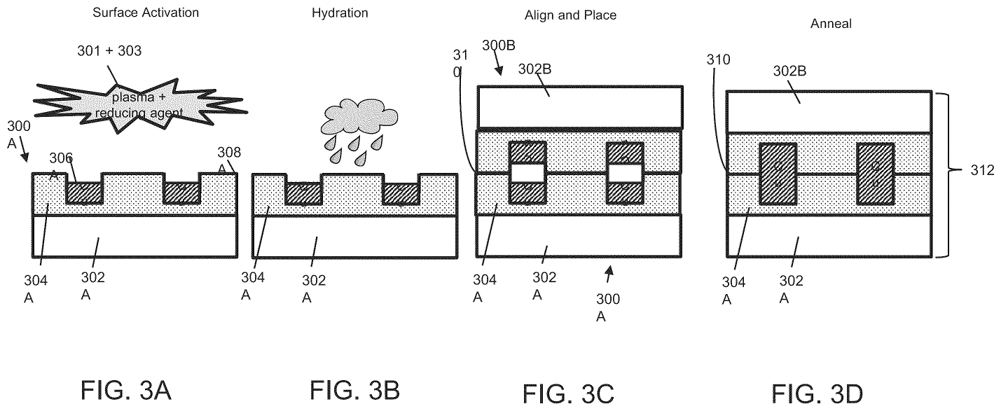

FIGS. 3A-3D illustrate a process of adding a reducing agent 303 to a typical plasma gas 301 during an activation of at least a bonding surface (such as 308A) of a wafer (such as 300A) in accordance with some embodiments. The embodiments as shown in FIGS. 3A-3D are similar to the embodiments as shown in FIGS. 2A-2D, but have some differences that will be explained below. For example, the operation illustrated in FIG. 3A is different from the operation illustrated in FIG. 2A, while the operations illustrated in FIGS. 3B-3D are similar to the operations illustrated in FIGS. 2B-2D. Parts or components 300, 302, 304, 306, 308, 310 and 312 in FIGS. 3A-3D respectively correspond to and are similar to parts or components 200, 202, 204, 206, 208, 210 and 212 as shown in FIGS. 2A-2D.

FIG. 3A illustrates a surface activation operation to at least one bonding surface (such as 308A) of a wafer (e.g., 300A) in accordance with some embodiments of the present disclosure. In some embodiments, an activation step is performed by using a plasma gas 301 and adding a reducing agent gas 303 to minimize or decrease modification of the conductive contacts (such as 306A). In some embodiments, the plasma gas 301 is generated by a plasma generator (not shown) that uses a slot-plane-antenna (SPA) technique. In some embodiments, the plasma gas 301 includes a O₂ or N₂ plasma gas. In some embodiments, the reducing agent gas 303 is selected from a group consisting of H₂, H₂O, H₂O₂, CO, CO₂, NH₃, CH₄, SO₂, H₂S, and NO, and in other embodiments, the reducing agent gas 303 is from a group consisting of volatile organic compounds (referred to as “VOCs” hereinafter), such as C₂H₆, C₃H₈, C₄H₁₀, C₂H₄ and C₂H₂.

During the activation, the plasma gas 301 can advantageously modify the bonding layer material to improve bonding strength thereof, however, may also disadvantageously modify the conductive material to create more resistive species. If only reducing agent gas 303 is used, all the materials on the bonding interface 310A will be reduced to their initial state, which can advantageously improve conductivity of the electrical contacts, however, may also disadvantageously reduce the bond strength of the material. By adding the reducing agent gas 303 to the plasma gas 301, through either a pulsed addition or a simultaneous addition, the strength of the bonding interface 310A can be advantageously increased, while advantageously minimizing the creation of high resistivity species at the surface of the conductive material 306A of the wafer 300A that receives a surface activation operation.

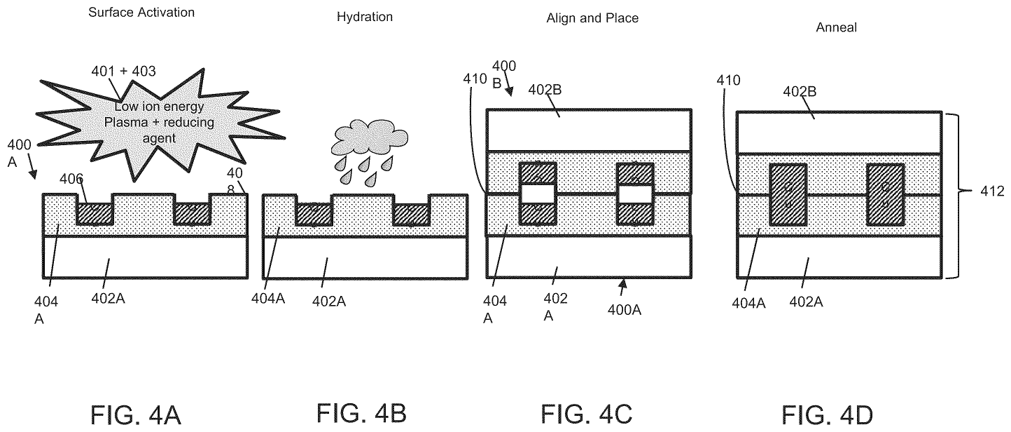

FIGS. 4A-4D illustrate a process of adding a reducing agent 403 to a particular plasma gas 401 during an activation of at least a bonding surface (such as 408A) of a wafer (such as 400A) in accordance with some embodiments. The embodiments as shown in FIGS. 4A-4D are similar to the embodiments as shown in FIGS. 2A-2D and FIGS. 3A-3D, but have some differences that will be explained below. For example, the operation illustrated in FIG. 4A is different from any of the operations illustrated in FIG. 2A and FIG. 3A, while the operations illustrated in FIGS. 4B-4D are similar to the operations illustrated in FIGS. 2B-2D and FIGS. 3B-3D. Parts or components 400, 402, 404, 406, 408, 410 and 412 in FIGS. 4A-4D respectively correspond to and are similar to parts or components 200, 202, 204, 206, 208, 210 and 212 as shown in FIGS. 2A-2D.

FIG. 4A illustrates a surface activation operation to at least one bonding surface (such as 408A) of a wafer (e.g., 400A) in accordance with some embodiments of the present disclosure. In some embodiments, an activation step is performed by using a plasma gas 401 and adding a reducing agent gas 403 to minimize or decrease modification of the conductive contacts (such as 406A). In some embodiments, the plasma 401 is generated by a plasma generator (not shown) that uses a slot-plane-antenna (SPA) technique. In some embodiments, the plasma 401 has a high electron density in a range between 1×10⁹ cm⁻³ and 1×10¹² cm⁻³, and in other embodiments, the plasma 201 has a high electron density in a range between 1×10¹⁰ cm⁻³ and 1×10¹¹ cm⁻³. In an embodiment, the electron temperature of the plasma 401 is less than 1 eV. In another embodiment, the electron temperature of the plasma 401 is in a range between 0.2 eV and 0.8 eV. In yet another embodiment, the electron temperature of the plasma 401 is in a range between 0.3 eV and 0.7 eV. In still yet another embodiment, the electron temperature of the plasma 401 is in a range between 0.4 eV and 0.6 eV. In some embodiments, the reducing agent gas 403 is selected from a group consisting of H₂, H₂O, H₂O₂, CO, CO₂, NH₃, CH₄, SO₂, H₂S, and NO, and in other embodiments, the reducing agent gas 403 is from a group consisting of volatile organic compounds (referred to as “VOCs” hereinafter), such as C₂H₆, C₃H₈, C₄H₁₀, C₂H₄ and C₂H₂.

As such, by using such a plasma having a low ion energy and high electron density, the thickness of the modified surface is very thin. By introducing such a reducing agent gas, the surface of the conductive material will be reduced. Through the combination of using such a plasma and adding such a reducing agent gas, bonding strength of the bonding surface (e.g., 408A) that receives a surface activation operation is improved, and all high resistive species can be eliminated from the surface of a conductive material after the activation process.

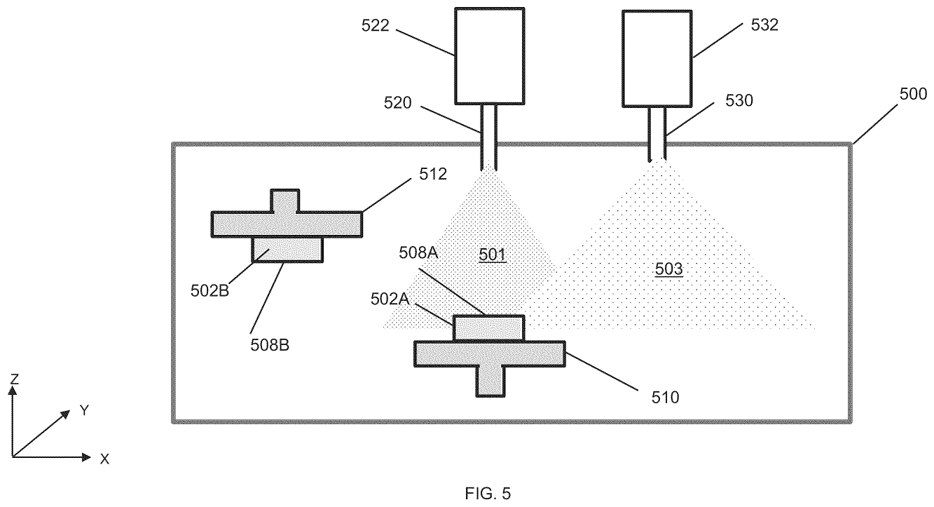

FIG. 5 is a view illustrating a surface activation chamber 500 in accordance with some embodiments. In some embodiments, as shown in FIG. 5, the surface activation chamber 500 is a vacuum chamber, and includes a first wafer carrier 510, a second wafer carrier 512, a plasma inlet port 520, a plasma generator 522, and a reducing agent inlet port 530.

In some embodiments, the first wafer carrier 510 is configured to hold and move a first wafer 502A that has a first surface 508A facing up. In some embodiments, the second wafer carrier 512 is configured to hold and move a second wafer 502B that has a second surface 508B facing down.

In some embodiments, the plasma generator 522 generates a plasma (or plasma gas) 501 by using a slot-plane-antenna (SPA) technique. In some embodiments, the plasma inlet port 520 is connected to the plasma generator 522, and configured to supply the plasma 501 into the chamber 500 and to direct the plasma 501 toward the first surface 508A of the first wafer 502A. In some embodiments, the plasma 501 generated by using the SPA technique has a high electron density and a low electron temperature in the chamber 500. In some embodiments, the plasma 501 has a high electron density in a range between 1×10⁹ cm⁻³ and 1×10¹² cm⁻³, and in other embodiments, the plasma 501 has a high electron density in a range between 1×10¹⁰ cm⁻³ and 1×10¹¹ cm⁻³. In an embodiment, the electron temperature of the plasma 501 is less than 1 eV. In another embodiment, the electron temperature of the plasma 501 is in a range between 0.2 eV and 0.8 eV. In yet another embodiment, the electron temperature of the plasma 501 is in a range between 0.3 eV and 0.7 eV. In still yet another embodiment, the electron temperature of the plasma 501 is in a range between 0.4 eV and 0.6 eV.

In some embodiments, the reducing agent inlet port 530 is connected to a reducing agent supply 532 and configured to supply a reducing agent (or reducing agent gas) 503 into the chamber 500. As such, the reducing agent gas 503 is combined with the plasma gas 501 within the chamber 500 to activate at least the first surface 508A of the first wafer 502A.

After performing a surface activation to at least the first surface 508A of the first wafer 502A, the first wafer 502A and the second wafer 502B are brought together and aligned each other, and then bonded each other in accordance with some embodiments. In some embodiments, the surface 508B of the second wafer 502B is similarly activated as the surface 508A of the first wafer 502A. In some embodiments, thermal energy is applied to the first wafer 502A and the second wafer 502B to anneal a bond interface formed therebetween.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims 1-20 and their equivalents, in which all terms are meant in their broadest reasonable sense unless otherwise indicated.

What is claimed is:

1. A method of bonding a first surface for bonding to a second surface, comprising:
exposing the first surface to a plasma having an electron density in a range between 1×10⁹ cm⁻³ and 1×10¹² cm⁻³ and including a reducing agent; and
bonding the first surface to the second surface.

2. The method of claim 1, wherein the electron density of the plasma is in a range between 1×10¹⁰ cm⁻³ and 1×10¹¹ cm⁻³.

3. The method of claim 1, wherein the plasma has an electron temperature of less than 1 eV.

4. The method of claim 3, wherein the electron temperature is in a range between 0.2 eV and 0.8 eV.

5. The method of claim 4, wherein the electron temperature is in a range between 0.3 eV and 0.7 eV.

6. The method of claim 1, further comprising:
before bonding the first surface to the second surface, exposing the second surface to the plasma.

7. The method of claim 1, further comprising:
after bonding the first surface to the second surface, annealing a bond interface between the first surface and the second surface.

8. A method of activating a first surface for bonding to a second surface, comprising:
exposing the first surface to a plasma having an electron density in a range between 1×10⁹ cm⁻³ and 1×10¹¹ cm⁻³, wherein the plasma is generated by a plasma generator using a slot-plane-antenna (SPA) technique; and
bonding the first surface to the second surface.

9. The method of claim 8, wherein the electron density of the plasma is in a range between 1×10¹⁰ cm⁻³ and 1×10¹¹ cm⁻³.

10. The method of claim 8, wherein the plasma has an electron temperature of less than 1 eV.

11. The method of claim 10, wherein the electron temperature is in a range between 0.2 eV and 0.8 eV.

12. The method of claim 8, wherein before bonding the first surface to the second surface, the second surface is also exposed to the plasma.

13. The method of claim 8, wherein after bonding the first surface to the second surface, a bond interface between the first surface and the second surface is annealed.

14. A method of activating a first surface for bonding to a second surface, comprising:
exposing the first surface to a plasma including a reducing agent, wherein the plasma is generated by a plasma generator using a slot-plane-antenna (SPA) technique; and
bonding the first surface to the second surface.

15. The method of claim 14, wherein the reducing agent is selected from a group consisting of H₂, H₂O, H₂O₂, CO, CO₂, NH₃, CH₄, SO₂, H₂S, and NO.

16. The method of claim 14, wherein the reducing agent is selected from a group consisting of volatile organic compounds.

17. The method of claim 16, wherein one of the volatile organic compounds is selected from a group consisting of C₂H₆, C₃H₈, C₄H₁₀, C₂H₄ and C₂H₂.

18. An activation chamber, comprising:
a first wafer carrier, configured to hold a first wafer having a first surface facing up;
a plasma generator, configured to generate a plasma using a slot-plane-antenna (SPA) technique;
a plasma inlet port, connected to the plasma generator and configured to direct the plasma toward the first surface of the first wafer, wherein the plasma has an electron density in a range between 1×10⁹ cm⁻³ and 1×10¹² cm⁻³ and an electron temperature of less than 1 eV; and
a reducing agent inlet port, connected to a reducing agent supply to supply a reducing agent into the chamber.

19. The chamber of claim 18, wherein the plasma has an electron temperature of less than 1 eV.

20. The chamber of claim 18, wherein the reducing agent is selected from a group consisting of H₂, H₂O, H₂O₂, CO, CO₂, NH₃, CH₄, SO₂, H₂S, NO, and a volatile organic compound.
